(19) United States
(12) Patent Application Publication
(10) Pub. No.: US 2014/0145663 A1
(43) Pub. Date: May 29, 2014

(54) ELECTRONIC APPARATUS CAPABLE OF CONTROLLING FLOW RATE OF AIR FROM COOLING FAN, METHOD OF CONTROLLING THE SAME, AND STORAGE MEDIUM

(71) Applicant: CANON KABUSHIKI KAISHA, Tokyo (JP)

(72) Inventor: Masakazu KITORA, Kawasaki-shi (JP)

(73) Assignee: CANON KABUSHIKI KAISHA, Tokyo (JP)

(21) Appl. No.: 14/089,809

(22) Filed: Nov. 26, 2013

(30) Foreign Application Priority Data
Nov. 26, 2012 (JP) 2012-257437

(51) Int. Cl. H05K 7/20

(52) U.S. Cl. CPC H05K 7/20209
USPC 318/471

(57) ABSTRACT

An electronic apparatus that is capable of properly controlling a cooling fan according to characteristics of a semiconductor device included in the electronic apparatus. Temperature characteristics indicative of a degree of increase in temperature of the semiconductor device are measured. A system controller controls the fan to operate at a predetermined air flow rate when a result of the temperature characteristics measurement indicates a degree of increase in temperature not smaller than a predetermined reference value, and controls the fan to operate at an air flow rate lower than the predetermined air flow rate when the measurement result indicates a degree of increase in temperature smaller than the predetermined reference value.

### BACKGROUND OF THE INVENTION

1. Field of the Invention

The present invention relates to an electronic apparatus that is capable of controlling a flow rate of air from a cooling fan, a method of controlling the same, and a storage medium.

2. Description of the Related Art

A demand for quietness of PCs and various types of image processing apparatuses has come to increase, and there has been known a technique that variably controls the flow rate of air from a fan by switching between full speed and half speed according to an operation mode of an apparatus (see Japanese Patent No. 3048947).

The image processing apparatus includes a controller that performs control using semiconductor devices, such as a CPU and an ASIC, and hence it is necessary to cool the controller so as to prevent the controller from becoming faulty or developing a malfunction due to generated heat or increased apparatus temperature.

Temperature characteristics of a semiconductor in a semiconductor device can be very different between individual units thereof. Further, various kinds of apparatuses using the semiconductor device are expected to be used in various environments.

FIGS. 10A and 10B show graphs of temperature characteristics of two individual CPUs, by way of example. As shown in the graph of the temperature characteristics in FIG. 10A, CPU A has temperature characteristics in which the temperature thereof operating under a predetermined load reaches a state of equilibrium without rising to the limit of a device operation-guaranteed temperature. On the other hand, as shown in the graph of the temperature characteristics in FIG. 10B, CPU B has the temperature characteristics in which the temperature thereof operating under a predetermined load becomes higher than the limit of the device operation-guaranteed temperature.

Further, FIGS. 11A and 11B show temperature characteristics of the same CPU when used under two respective different operational environments. As is apparent from FIGS. 11A and 11B, there is such a difference in temperature characteristics that the temperature of the CPU is within the limit of the device operation-guaranteed temperature under an environment in which the temperature is around 25° C., whereas the temperature of the CPU becomes higher than the limit of the device operation-guaranteed temperature under an environment in which the temperature is around 35° C.

In a case where the fan is controlled by estimating load on the CPU based on the operating mode of the apparatus as in the conventional apparatus, when the apparatus is in an operation mode under such load as will cause the temperature of the CPU B shown in FIG. 10B to rise to the limit of the device operation-guaranteed temperature, or in an operation mode under such load as will cause the temperature of the CPU under the environment at 35° C. as shown in FIG. 11B to rise beyond the limit of the device operation-guaranteed temperature, it is necessary to control the temperature such that the temperature of the CPU from is prevented from exceeding the device operation-guaranteed temperature e.g. by increasing the flow rate of air from the fan.

However, the conventional control increases the flow rate of air from the fan even for the CPU A having excellent temperature characteristics or the CPU under the environment at 25° C., the temperature of neither of which increases to the limit of the device operation-guaranteed temperature, causing degradation of quietness of the apparatus. Thus, the conventional technique has a problem that fan control is not always properly performed.

### SUMMARY OF THE INVENTION

The present invention provides an electronic apparatus that is capable of properly controlling a cooling fan according to characteristics of a semiconductor device included in the electronic apparatus, a method of controlling the same, and a storage medium.

In a first aspect of the present invention, there is provided an electronic apparatus that includes a semiconductor device and is capable of controlling a flow rate of air from a fan for cooling the semiconductor device, comprising a measurement unit configured to measure temperature characteristics indicative of a degree of increase in temperature of the semiconductor device, and a control unit configured to control the fan to operate at a predetermined air flow rate in a case where a result of the temperature characteristics measurement by the measurement unit indicates a degree of increase in temperature not smaller than a predetermined reference value, and control the fan to operate at an air flow rate lower than the predetermined air flow rate in a case where the measurement result indicates a degree of increase in temperature smaller than the predetermined reference value.

In a second aspect of the present invention, there is provided a method of controlling an electronic apparatus that includes a semiconductor device and is capable of controlling a flow rate of air from a fan for cooling the semiconductor device, comprising measuring temperature characteristics indicative of a degree of increase in temperature of the semiconductor device, and controlling the fan to operate at a predetermined air flow rate in a case where a result of the temperature characteristics measurement by said measuring indicates a degree of increase in temperature not smaller than a predetermined reference value, and controlling the fan to operate at an air flow rate lower than the predetermined air flow rate in a case where the result of the temperature characteristics measurement indicates a degree of increase in temperature smaller than the predetermined reference value.

In a third aspect of the present invention, there is provided a non-transitory computer-readable storage medium storing a computer-executable program for executing a method of controlling an electronic apparatus that includes a semiconductor device and is capable of controlling a flow rate of air from a fan for cooling the semiconductor device, wherein the method comprises measuring temperature characteristics indicative of a degree of increase in temperature of the semiconductor device, and controlling the fan to operate at a predetermined air flow rate in a case where a result of the temperature characteristics measurement by said measuring indicates a degree of increase in temperature not smaller than a predetermined reference value, and controlling the fan to operate at an air flow rate lower than the predetermined air flow rate in a case where the result of the temperature characteristics measurement indicates a degree of increase in temperature smaller than the predetermined reference value.

According to the present invention, it is possible to provide an electronic apparatus that is capable of properly controlling a cooling fan according to characteristics of a semiconductor device included in the electronic apparatus, a method of controlling the same, and a storage medium.

Further features of the present invention will become apparent from the following description of exemplary embodiments with reference to the attached drawings.

### BRIEF DESCRIPTION OF THE DRAWINGS

FIG. 1 is a block diagram of an image processing apparatus according to an embodiment of the present invention.

FIG. 2 is a state transition diagram of the image processing apparatus shown in FIG. 1.

FIGS. 3A and 3B are diagrams useful in explaining a temperature slope.

FIG. 4 is a flowchart of a temperature slope-based temperature characteristic measurement process executed by a system controller appearing in FIG. 1.

FIG. 5 is a state transition diagram of the image processing apparatus in a case where a flag FAN_CONT is determined based on the temperature slope.

FIG. 6 is a flowchart of an elapsed time-based temperature characteristic measurement process executed by the system controller appearing in FIG. 1.

FIG. 7 is a flowchart of a periodical temperature slope-based temperature characteristic measurement process periodically executed by the system controller appearing in FIG. 1 in a standby state.

FIG. 8 is a state transition diagram of the image processing apparatus in a case where the flag FAN_CONT is periodically determined.

FIG. 9 is a state transition diagram of the image processing apparatus in a case where a loaded condition of the system controller is used.

FIGS. 10A and 10B are temperature characteristic graphs showing temperature characteristics of respective different individual CPUs.

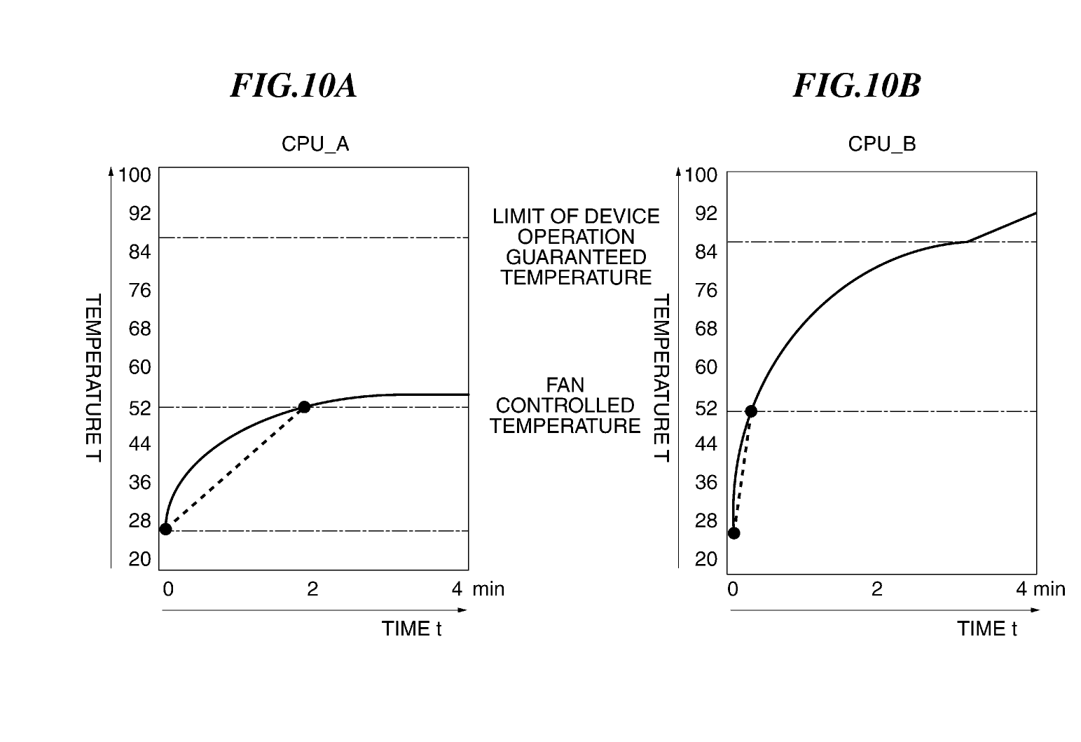

FIGS. 11A and 11B are temperature characteristic graphs showing temperature characteristics of the same CPU under different operational environments.

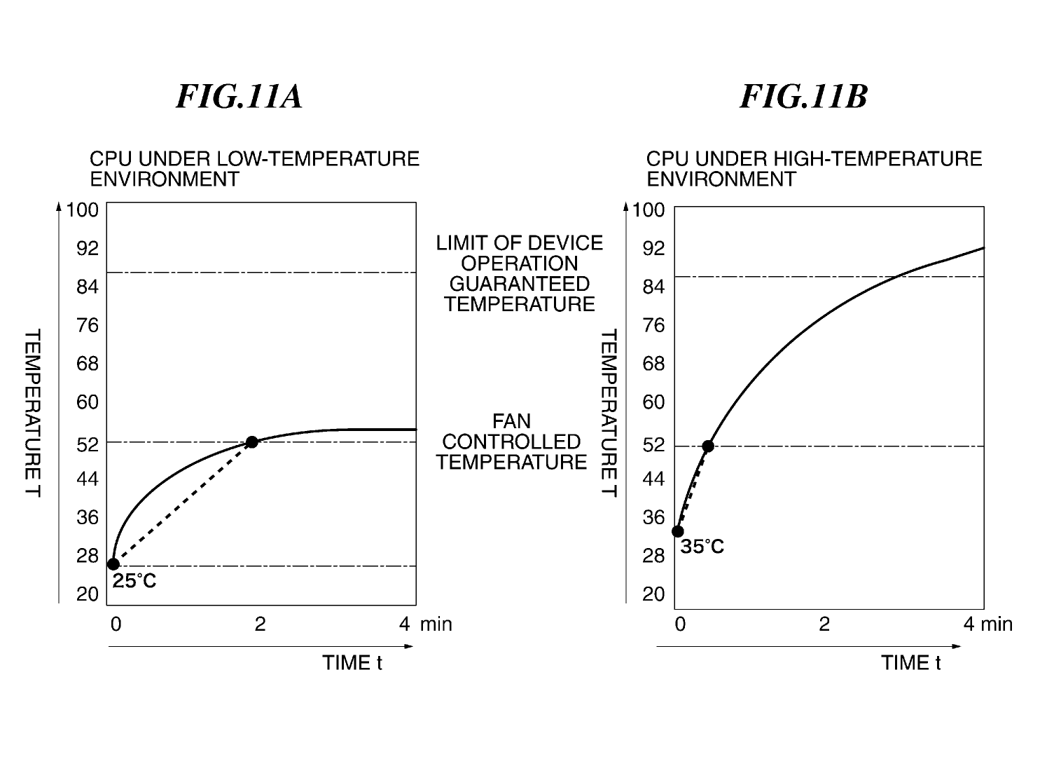

### DESCRIPTION OF THE EMBODIMENTS

The present invention will now be described in detail below with reference to the accompanying drawings showing embodiments thereof. In the present embodiment, a description will be given of an example in which an electronic apparatus according to the present invention is applied to an image processing apparatus.

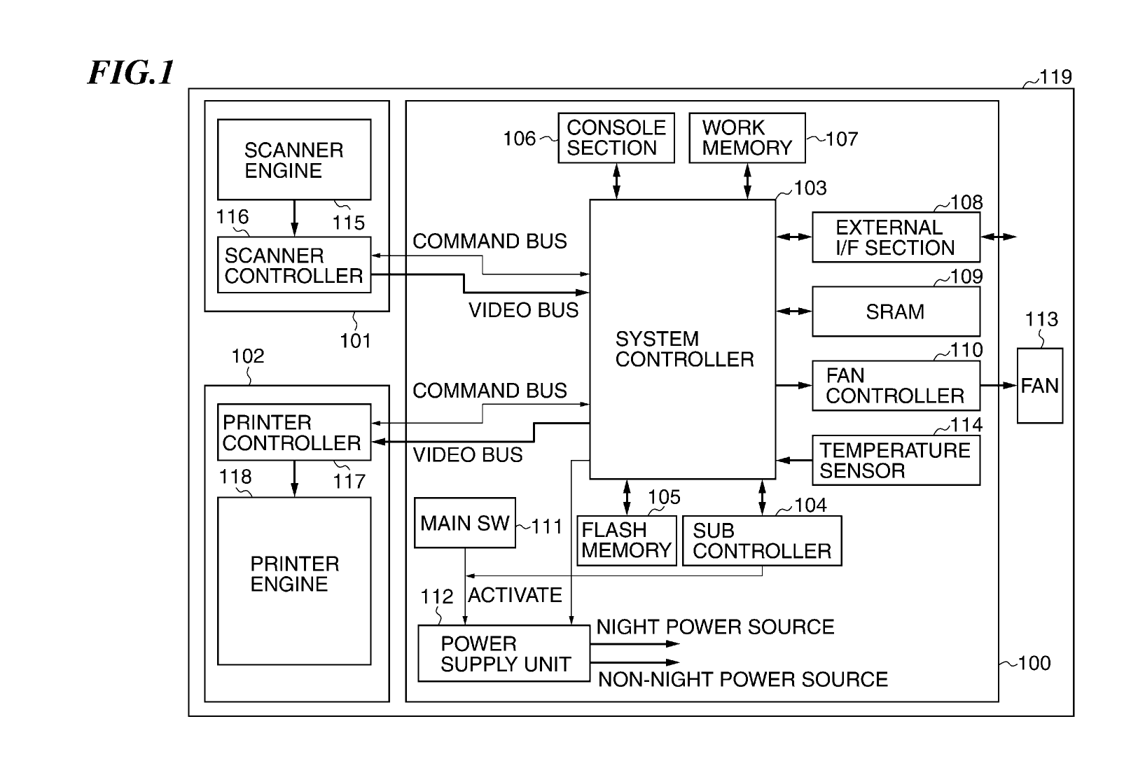

FIG. 1 is a block diagram of an image processing apparatus 119 according to the embodiment of the present invention.

Referring to FIG. 1, the image processing apparatus 119 comprises a system control unit 100, a scanner 101, a printer 102, and a fan 113.

The system control unit 100 controls the overall operation of the image processing apparatus 119. The scanner 101 reads image data. The printer 102 records image data subjected to image processing and output by the system control unit 100, in a recording medium.

A system controller 103 in the system control unit 100 processes the image data, and is connected to component elements via general-purpose interfaces or dedicated interfaces. The system controller 103 may be implemented by a general-purpose CPU, or a SOC (system on chip), such as an ASIC (application-specific integrated circuit). Further, the system controller 103 may be implemented by a chip set integrating a plurality of devices that realize functions of an IO section, a processor, etc. As described above, although the image processing apparatus 119 according to the present embodiment includes various kinds of semiconductor devices (hereinafter referred to as the “devices”), the system controller 103 is a device to be cooled by the fan 113, described hereinafter.

A sub controller 104 is a controller that controls image processing and the like, performed by the image processing apparatus 119. Similar to the system controller 103, the sub controller is not limited to a specific form, but may have any of various suitable forms depending on the system requirements.

A flash memory 105 is used for storing user programs. A console section 106 receives operations from a user, and displays the status and information of the image processing apparatus 119 to a user.

A work memory 107 is used as a work area for the system controller 103, and is used for temporarily storing image data.

When the image processing apparatus 119 is connected to a network environment, such as a LAN, which is a general-purpose interface, an external interface section 108 provides interfacing for transmission of scanned image data to the network environment and reception of print image data and screen data for displaying a screen browsed by a web browser from the same.

An SRAM 109 is used for storing information necessary for the system control unit 100, such as address information of external apparatuses and counter information, even after a power supply unit 112 is switched off.

A fan controller 110 under the control of the system controller 103 is capable of electrically controlling the rotation and stop of the fan 113, and the magnitude of the flow rate of air from the fan 113. A temperature sensor 114 is used for measuring temperature of the system controller 103.

A main SW 111 is a switch for controlling the power on and power off of the image processing apparatus 119, and a signal output from the main SW 111 is input to the power supply unit 112.

The power supply unit 112 supplies a night power and a non-night power to the system control unit 100 according to an output signal from the main SW 111.

A scanner engine 115 in the scanner 101 reads an original, and generates image data converted to an electric signal.

A scanner controller 116 is connected to the system controller 103 via a command bus and a video bus, which are dedicated interfaces, to transmit image data and perform command communication with the system controller 103.

A printer controller 117 in the printer 102 is connected to the system controller 103 via a command bus and a video bus, which are dedicated interfaces, to receive image data and perform command communication with the system controller 103.

A printer engine 118 records image data transmitted from the system control unit 100 to the printer controller 117 on a recording medium.

Next, out of various processing operations realized by the image processing apparatus 119, a copy operation, a print operation, a scan/transfer operation (hereinafter referred to as “send”), and a web-browsing operation will be briefly described.

First, the copy operation will be described. The scanner 101 electrically reads an original set on an original platen glass, not shown, provided on the scanner engine 115. The image data converted from analog to digital and corrected by the scanner controller 116 is transferred to the system controller 103 via the video bus.

The transferred image data is temporarily stored in the work memory 107, and is subjected to predetermined image processing and image compression by the sub controller 104. Then, the compressed image data is stored in an image area of the flash memory 105.

Next, the printer 102 and the system control unit 100 communicate with each other via the command bus, and the system control unit 100 stores the compressed image data read from the flash memory 105 in the work memory 107, in synchronism with the operation of the printer 102.

Then, the stored image data is decompressed by the sub controller 104, and is stored in the work memory 107. Then, the system controller 103 transfers the image data to the printer 102. In the printer 102, the printer controller 117 converts the transferred image data to a recording signal, and performs recording on the recording medium using the converted recording signal.

Next, the print operation will be described. The image processing apparatus 119 receives print data sent from an external apparatus, such as a PC, via the external interface section 108, and stores the received print data in the work memory 107.

The system controller 103 analyzes the print data, converts the print data to image data, and then stores the image data in the work memory 107. Then, predetermined image processing and image compression are performed on the image data by the sub controller 104, and then the system controller 103 stores the compressed data in the flash memory 105. The operation for printing the stored image data is executed according to the same process as the copy operation.

Next, the send operation will be described. Reading of an image is performed according to the same procedure as that for the copy operation. Image processing and image compression are performed on the read image, and the compressed image data is stored in the flash memory 105. Next, the system controller 103 reads out the image data from the flash memory 105, and stores the image data into the work memory 107, while communicating with the external apparatus, which is a destination designated from the console section 106, via the external interface section 108, and when the communication is established by negotiation, the system controller 103 transmits the image data to the external apparatus.

Finally, the web-browsing operation will be described. When the web-browsing operation is selected via the console section 106, the system controller 103 acquires URL information designated by an address bar displayed on the console section 106.

Then, the system controller 103 communicates with the apparatus identified by the designated URL via the external interface section 108 to acquire screen data to be displayed, and stores the acquired data in the work memory 107. Then, the system controller 103 converts the acquired screen data to bitmap data to be displayed on the console section 106, in another area of the work memory 107. The converted bitmap data is transferred to the console section 106 whereby an image is rendered on the display screen of the console section 106.

In the image processing apparatus 119 according to the present embodiment, the system controller 103 controls the flow rate of air from the fan 113 according to the operating condition of the apparatus and characteristics of devices and the environment. The control of the flow rate of air from the fan 113 is realized by a known method, such as a method of controlling voltage applied to the fan 113.

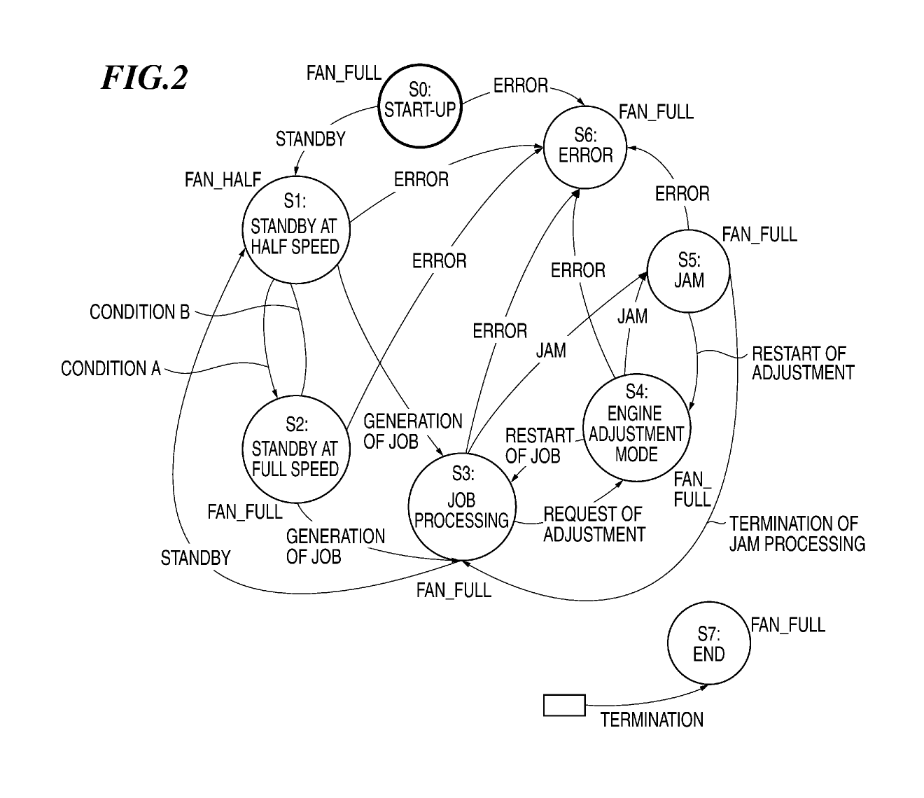

FIG. 2 is a state transition diagram of the image processing apparatus 119 shown in FIG. 1.

In the state transition diagram shown in FIG. 2, eight states of the image processing apparatus 119 from SO to S7 are illustrated. The operating condition of the fan in each state is expressed by a variable of FAN_FULL or FAN_HALF. The variable FAN_FULL indicates an operation condition in which the fan is rotating at full speed, and the variable FAN_HALF indicates an operation condition in which the fan is rotating at half speed.

Hereafter, each state in the state transition diagram of the image processing apparatus 119, illustrated in FIG. 2, will be described.

The state SO of “start-up” indicates a start-up state in which the image processing apparatus 119 is powered on to be activated and enters an initial state. In this state, initialization of the image processing apparatus 119 is executed. The fan is in the state of FAN_FULL.

In this state, if the system controller 103 detects an error from any of the blocks of the system control unit 100, the scanner 101, and the printer 102, the image processing apparatus 119 is shifted to the state S6. If no error is detected, upon termination of the initialization of the apparatus, the image processing apparatus 119 is shifted to the state S1.

The state S1 of “standby at half speed” indicates a standby state of the image processing apparatus 119. The fan is in the state of FAN_HALF.

If the system controller 103 detects an error from any of the blocks of the system control unit 100, the scanner 101, and the printer 102 in the state S1, the image processing apparatus 119 is shifted to the state S6. On the other hand, if an image processing job, such as a scan job, a print job, and a send job, is generated by the system controller 103, the image processing apparatus 119 is shifted to the state S3.

Further, if a condition A, described hereinafter, is satisfied, the image processing apparatus 119 is shifted to the state S2.

The state S2 of “standby at full speed” indicates a standby state of the image processing apparatus 119. Among the standby states, the state S2 is a state in which there is a possibility that the system controller 103 is in a high-load condition due to application of heavy load thereto. The fan is in the state of FAN_FULL.

If the system controller 103 detects an error from any of the blocks of the system control unit 100, the scanner 101, and the printer 102 in the state S2, the image processing apparatus 119 is shifted to the state S6. On the other hand, if an image processing job, such as a scan job, a print job, and a send job, is generated by the system controller 103, the image processing apparatus 119 is shifted to the state S3.

Further, if a condition B, described hereinafter, is satisfied, the image processing apparatus 119 is shifted to the state S1.

The state S3 of “job processing” indicates that the image processing apparatus 119 is in a job processing operation. That is, the state S3 is a state in which the image processing apparatus 119 is processing a job, such as a copy job, a print job, and a send job. The fan is in the state of FAN_FULL.

When in the state S3, if the system controller 103 detects an error from any of the blocks of the system control unit 100, the scanner 101, and the printer 102, the image processing apparatus 119 is shifted to the state S6. Further, if the system controller 103 is notified of a paper jam from the scanner 101 or the printer 102, the image processing apparatus 119 is shifted from the state S3 to the state S5.

Further, when in the state S3, if a request of adjustment processing is received from the scanner 101 or the printer 102, the image processing apparatus 119 is shifted to the state S4. If the job processing is normally terminated in the state S3, the image processing apparatus 119 is shifted to the state S1.

The state S4 of “engine adjustment mode” indicates that the image processing apparatus 119 is being subjected to adjustment. The adjustment includes execution of correction of image data read by the scanner engine 115, correction of image data to be output by the printer engine 118, and registration correction. The fan is in the state of FAN_FULL.

When in the state S4, if the system controller 103 detects an error from any of the blocks of the system control unit 100, the scanner 101, and the printer 102 in the state S4, the image processing apparatus 119 is shifted to the state S6. Further, if the system controller 103 is notified of a paper jam from the scanner 101 or the printer 102, the image processing apparatus 119 is shifted to the state S5. When the adjustment processing is terminated, the image processing apparatus 119 is shifted to the state S3.

The state S5 of “jam” indicates a state in which a paper jam is caused in the scanner engine 115 or the printer engine 118. The fan is in the state of FAN_FULL.

When in the state S5, if the system controller 103 detects an error from any of the blocks of the system control unit 100, the scanner 101, and the printer 102, the image processing apparatus 119 is shifted to the state S6. Further, when processing for clearing the paper jam is terminated to cause the system controller 103 to be notified of clearance of the jam from the scanner 101 or the printer 102, the image processing apparatus 119 is shifted to the preceding state (S3 or S4).

The state S6 of “error” indicates a state in which an abnormality has occurred in the image processing apparatus 119 during operation thereof. The fan is in the state of FAN_FULL. In this state, error handling is executed. When the error handling is completed, the image processing apparatus 119 is shifted to the state S7.

The state S7 of “end” indicates the end of the operation of the image processing apparatus 119. In the state S7, processing for terminating the operation of the image processing apparatus 119 is executed, and the image processing apparatus 119 is powered off.

In the present embodiment, switching the state between S1 and S2 in the above-described state transition diagram is controlled using the conditions A and B.

In controlling the fan 113, first, temperature characteristics are measured by a temperature characteristic measurement process so as to determine a fan control condition FAN_CONT according to individual variation of the system controller 103 and environmental conditions.

The temperature characteristic measurement process is executed at three timings, i.e. when the image processing apparatus 119 is powered on, when image processing (job), such as copy, print, and send, is not executed for a predetermined time period, and when temperature characteristic measurement is instructed by a user via the console section 106. When any of these conditions is satisfied, the temperature characteristic measurement process is executed.

Further, the above-mentioned FAN_CONT is a flag which is set to 0 or 1 (hereinafter referred to as the flag FAN_CONT), and when a degree of increase in temperature is larger than a predetermined reference value, the flag is set to 1. Further, when a degree of increase in temperature is smaller than the predetermined reference value, the flag is set to 0. The value of the flag FAN_CONT is used for the conditions A and B. In the present embodiment, as a rule, when a result of the temperature characteristics measurement indicates a degree of increase in temperature equal to or larger than the predetermined reference value, the fan 113 is controlled to operate at a predetermined air flow rate, whereas when a result of the temperature characteristics measurement indicates a smaller degree of increase in temperature than the predetermined reference value, the fan 113 is controlled to operate at an air flow rate lower than the predetermined air flow rate. Therefore, according to the present embodiment, it is possible to properly control the fan according to the characteristics of a semiconductor device included in the electronic apparatus.

The flag FAN_CONT is determined using the temperature slope or time, and methods of the determination using these parameters will be sequentially described.

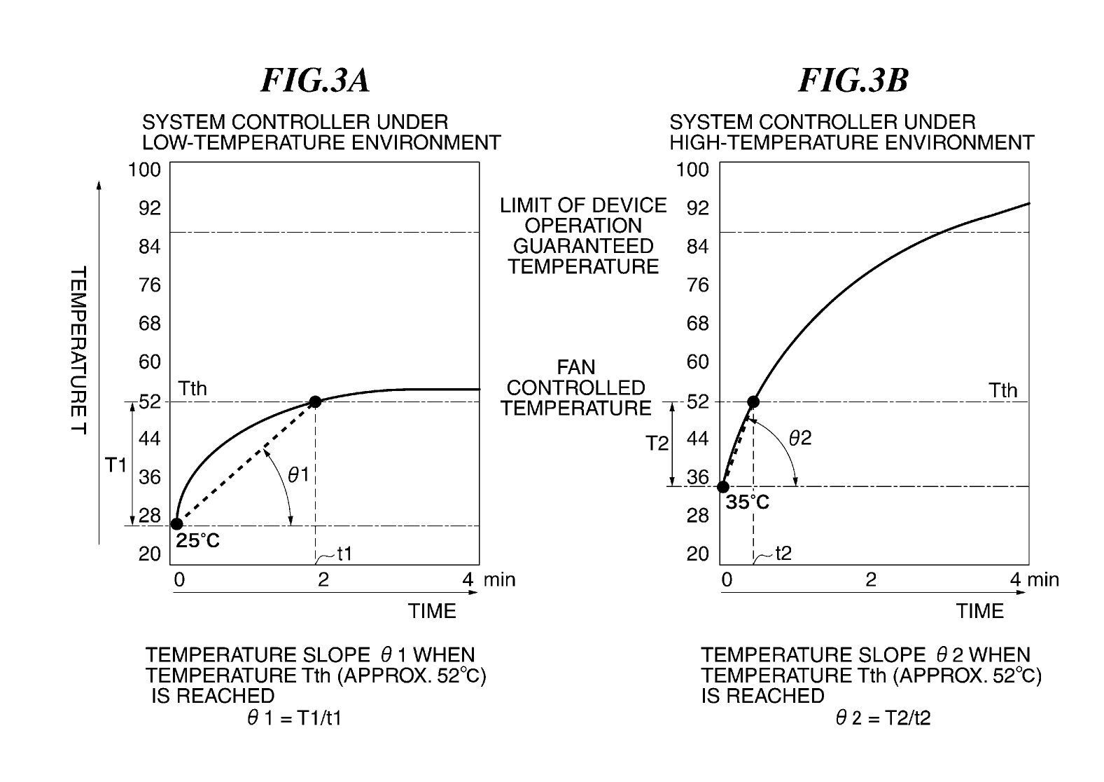

FIGS. 3A and 3B are diagrams useful in explaining the temperature slope.

FIG. 3A shows temperature characteristics of the system controller 103 under a low-temperature environment, and FIG. 3B shows temperature characteristics of the system controller 103 under a high-temperature environment. Further, the vertical axis of the graph represents temperature, and the horizontal axis of the same represents time.

In FIGS. 3A and 3B, time periods required for the temperature of the system controller 103 to reach a predetermined temperature Tth (e.g. approx. 52° C.) are measured as t1 and t2, respectively.

Assuming that a difference in temperature is represented by ΔT, and a time period required to reach the predetermined temperature Tth is represented by t, the temperature slope according to the present embodiment is calculated by ΔT/t. Thus, the temperature slope is a temperature characteristic indicative of a degree of device temperature increase per unit time.

Then, the temperature slopes θ1 and θ2 are calculated from the time periods t1 and t2 and the temperature differences T1 and T2 between the predetermined temperature Tth and the temperatures at the start of measurement in FIGS.3A and 3B.

In FIG. 3A, the time period t1 required for the temperature to reach the temperature Tth is equal to approximately two minutes, and the temperature slope θ1 at the time point of the lapse of the time period t1 is obtained by θ1=(52-25)° C.÷approx. 2 min.=approx. 12.5° C./min.

On the other hand, in FIG. 3B, the temperature reaches the temperature Tth at the time point of the lapse of the time period t2=less than one minute (approx. 0.4 min.). The temperature slope θ2 at the time point of the lapse of the time period t2 is obtained by θ2=(52-35)° C.÷approx. 0.4 min.=approx. 43° C./min.

Assuming that θth represents a threshold value of the temperature slope at which the temperature of the system controller 103 rises to a limit Tmax (approx. 85° C.) of device operation-guaranteed temperature to enter a state of equilibrium, and the threshold value θth is 25° C./min, in the case of FIG. 3A, θ1<θth holds, whereas in the case of FIG. 3B, θ2>θth holds.

In view of this, a calculated temperature slope is compared with the threshold value, and if the calculated temperature slope is smaller than the threshold value, the flag FAN_CONT is set to 0, whereas if the calculated temperature slope is not smaller than the threshold value, the flag FAN_CONT is set to 1.

Therefore, in the case of FIG. 3A, the flag FAN_CONT is set to 0, and in the case shown in FIG. 3B, the flag FAN_CONT is set to 1.

Note that in another image processing apparatus having the same configuration as the image processing apparatus 119, there is a case where the flag FAN_CONT is set to 1 as the measurement result in the same temperature characteristic measurement mode regardless of whether it is under the low-temperature or high-temperature environment, or a case where the flag FAN_CONT is always set to 0. Such an inconvenience is caused not by an environmental condition but by a difference in temperature characteristics between individual units of the system controller.

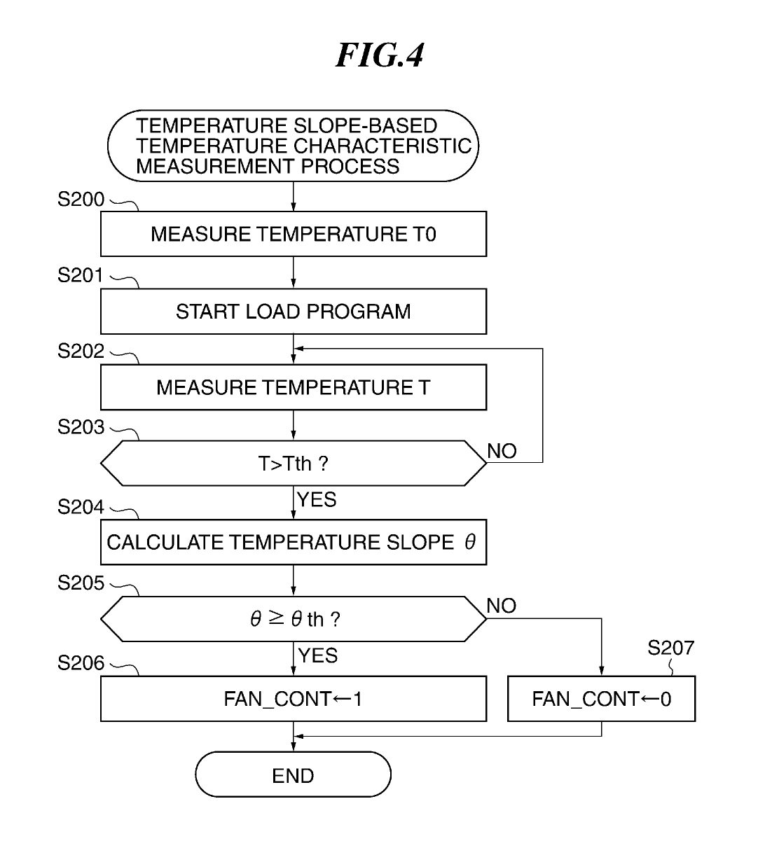

FIG. 4 is a flowchart of a temperature slope-based temperature characteristic measurement process executed by the system controller 103 appearing in FIG. 1.

In FIG. 4, a temperature T0 is measured using the temperature sensor 114 (step S200), and a load program is started (step S201).

The load program includes a load test program for the system controller 103, language analysis of print data simulating an actual job, conversion from an intermediate language to print data, rasterizing a bitmap image to be displayed on a screen of the console section, and so on. However, the load program is not limited to the above-mentioned programs but any suitable program may be used insofar as a sufficient degree of an operating ratio of the system controller 103 can be expected.

Then, the temperature T after the load program has been operated is measured (step S202), and if the temperature T becomes higher than the predetermined threshold value Tth (YES to the step S203), the temperature slope θ is calculated (step S204). The step S204 corresponds to an operation of a measurement unit configured to measure the temperature characteristics indicative of a degree of increase in temperature of a semiconductor device.

Then, the system controller 103 determines whether or not the temperature slope θ is not smaller than the predetermined threshold value θth (step S205). If it is determined in the step S205 that the temperature slope θ is not smaller than the predetermined threshold value θth (YES to the step S205), the flag FAN_CONT is set to 1 (step S206), followed by terminating the present process.

On the other hand, if it is determined in the step S205 that the temperature slope θ is smaller than the predetermined threshold value θth (NO to the step S205), the flag FAN_CONT is set to 0 (step S207), followed by terminating the present process. As described above, in the temperature slope-based temperature characteristic measurement process in FIG. 4, the temperature characteristics are measured based on the time period t which elapses after load is applied to the device, and the increased temperature ΔT of the device after the load is applied to the device.

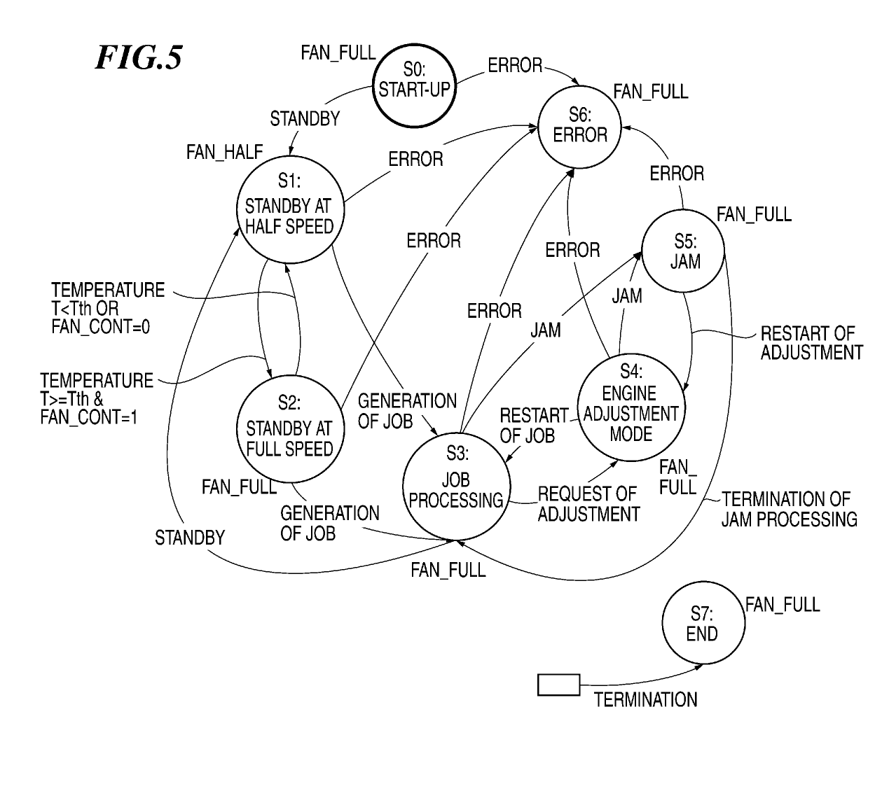

FIG. 5 is a state transition diagram of the image processing apparatus 119 in the case where the flag FAN_CONT is determined based on the temperature slope.

Referring to FIG. 5, the condition A is defined as the flag FAN_CONT=1 and the temperature T≧Tth, and the condition B is defined as the flag FAN_CONT=0 or the temperature T<Tth.

The condition A is a condition for shifting the image processing apparatus 119 from the state S1 to the state S2. Therefore, if the temperature T measured when the image processing apparatus 119 is in the state S1 is not lower than the temperature Tth so that the flag FAN_CONT is set to 1, the image processing apparatus 119 is shifted to the state S2. As described hereinabove, the state S1 and the state S2 are both standby states, and processing being executed in this state is e.g. a web browsing operation.

There is a possibility that such processing has caused execution of an operation which increases the operating ratio of the system controller 103, and it is presumed that the temperature of the system controller 103 will become very high. For this reason, the image processing apparatus 119 is shifted to the state S2.

The condition B is a condition for shifting the image processing apparatus 119 from the state S2 to the state S1. Therefore, if the temperature T measured when the image processing apparatus 119 is in the state S2 is lower than the temperature Tth, or the flag FAN_CONT is set to 0 by the temperature characteristic measurement process, the image processing apparatus 119 is shifted to the state S1.

For example, when processing, such as the web-browsing operation mentioned above, is terminated, causing a decrease in the operating ratio of the system controller 103, the image processing apparatus 119 is shifted to the state S1.

The fan control is thus executed by the slope-based temperature characteristic measurement process, using the conditions A and B defined as described above.

That is, when the temperature of the device is not lower than the predetermined temperature and also the result of the temperature characteristics measurement indicates a larger degree of increase in temperature than the reference value θth, the system controller 103 controls the fan 113 to operate at the predetermined air flow rate (full speed).

Further, when the temperature of the device is lower than the predetermined temperature or the result of the temperature characteristics measurement indicates a smaller degree of increase in temperature than the reference value θth, the system controller 103 controls the fan 113 to operate at an air flow rate lower than the predetermined air flow rate (half speed).

Next, a process for determining the flag FAN_CONT based on a predetermined elapsed time period will be described.

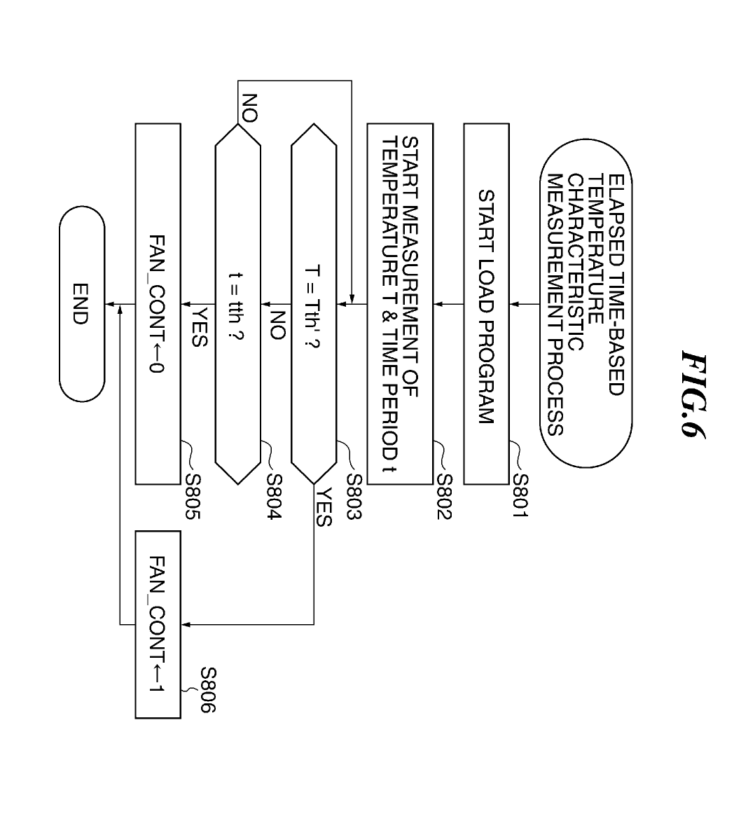

FIG. 6 is a flowchart of an elapsed time-based temperature characteristic measurement process executed by the system controller 103 appearing in FIG. 1.

Referring to FIG. 6, first, the load program is started (step S801). The load program used in this step is the same as described hereinabove in the temperature slope-based temperature characteristic measurement process in FIG. 4.

Then, measurement of the temperature T and the time period t is started (step S802). Hereafter, the temperature T and the time t are continuously measured.

The system controller 103 determines whether or not the temperature T has reached a predetermined temperature Tth′ (step S803). If it is determined in the step S803 that the temperature T has reached the predetermined temperature Tth′ (YES to the step S803), the flag FAN_CONT is set to 1 (step S806), followed by terminating the present process. The fact that the answer to the question of the step S803 is affirmative means that an increase in the temperature T is large, and hence the flag FAN_CONT is set to 1.

On the other hand, if it is determined in the step S803 that the temperature T has not reached the predetermined temperature Tth (NO to the step S803), the system controller 103 determines whether or not the measured time period t is equal to a predetermined time period tth (step S804).

If it is determined in the step S804 that the measured time period t is not equal to the predetermined time period tth (NO to the step S804), the system controller 103 returns to the step S803.

On the other hand, if it is determined in the step S804 that the time period t is equal to the predetermined time period tth (YES to the step S804), the flag FAN_CONT is set to 0 (step S805), followed by terminating the present process. The fact that the answer to the question of the step S804 is affirmative means that an increase in the temperature T is small, and hence the flag FAN_CONT is set to 0.

As described above, in the elapsed time-based temperature characteristics measurement process in FIG. 6, the temperature characteristics are measured according to whether or not the temperature of the device increases to a predetermined temperature before the predetermined time period elapses after load is applied to the device. More specifically, if the temperature of the device increases to the temperature Tth′ before the predetermined time period tth elapses, the measurement result indicates that a degree of increase in temperature is larger than the predetermined reference value. On the other hand, if the temperature of the device has not increased to the temperature Tth′ until the predetermined time tth has elapsed, the measurement result indicates that a degree of increase in temperature is smaller than the predetermined reference value.

Although the above-described temperature characteristic measurement processes shown in FIGS. 4 and 6 are executed at one of the above-mentioned three timings, they may be continually executed in the standby state.

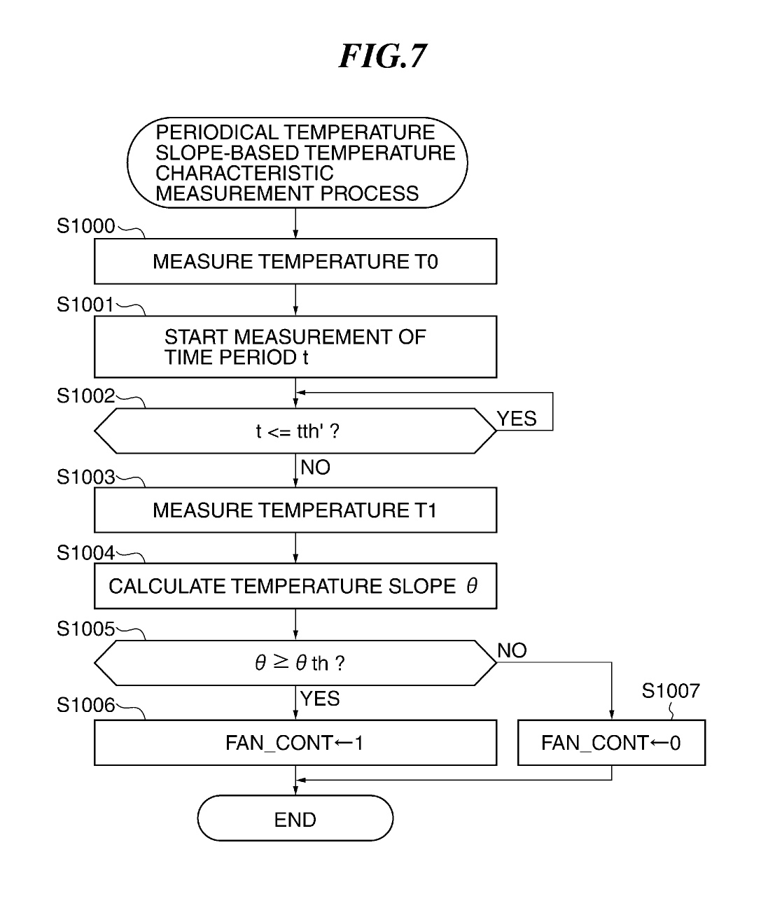

FIG. 7 is a flowchart of a periodical temperature slope-based temperature characteristic measurement process periodically executed by the system controller 103 appearing in FIG. 1 in the standby state.

Referring to FIG. 7, the temperature T0 is measured using the temperature sensor 114 (step S1000), and measurement of the time period t is started (step S1001).

Then, when the time period t started to be measured becomes equal to a predetermined time period tth′ (step S1002), a temperature T1 is measured (step S1003), and the temperature slope θ is calculated (step S1004). The temperature slope θ calculated in this step is obtained by dividing the temperature difference ΔT between T0 and T1 by the time period t.

Then, the system controller 103 determines whether or not the calculated temperature slope θ is not smaller than the predetermined threshold value θth (step S1005). If it is determined in the step S1005 that the calculated temperature slope θ is not smaller than the predetermined threshold value θth (YES to the step S1005), the flag FAN_CONT is set to 1 (step S1006), followed by terminating the present process.

On the other hand, if it is determined in the step S1005 that the temperature slope θ is smaller than the predetermined threshold value θth (NO to the step S1005), the flag FAN_CONT is set to 0 (step S1007), followed by terminating the present process.

As described above, according to the periodical temperature slope-based temperature characteristic measurement process in FIG. 7, the temperature characteristics are measured based on the predetermined time period tth′ periodically at predetermined time intervals.

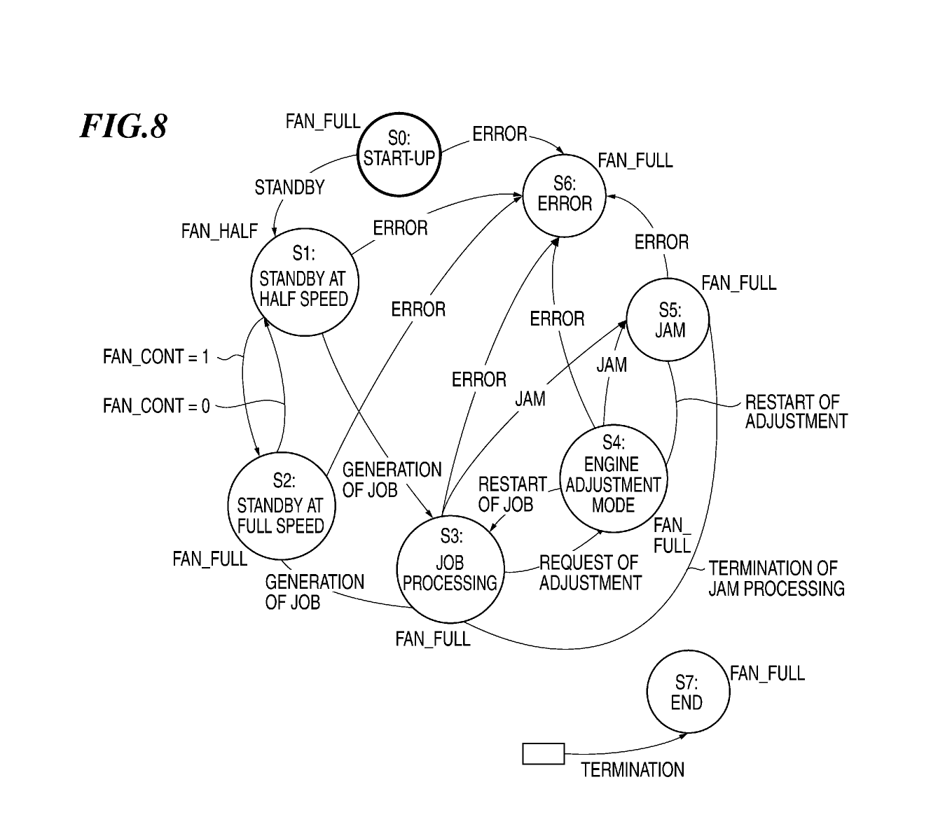

FIG. 8 is a state transition diagram of the image processing apparatus 119 in a case where the flag FAN_CONT is determined by the periodical temperature slope-based temperature characteristic measurement process.

Referring to FIG. 8, in the state S1, the flag FAN_CONT is periodically updated according to the periodical temperature slope-based temperature characteristic measurement process shown in FIG. 7. As a result of the periodical temperature slope-based temperature characteristic measurement process, if the flag FAN_CONT=1 is set, the image processing apparatus 119 is shifted to the state S2.

On the other hand, also in the state S2, the flag FAN_CONT is periodically updated according to the periodical temperature slope-based temperature characteristic measurement process shown in FIG. 7. As a result of the periodical temperature slope-based temperature characteristic measurement process, if the flag FAN_CONT=0 is set, the image processing apparatus 119 is shifted to the state S1.

In the above-described embodiments, the description has been given of the method of determining the flag FAN_CONT. Next, a description will be given of fan control using a load state of the system controller 103, as a variation of the present embodiment.

In general, an OS (operating system) is provided with a tool for measuring load, such as a performance monitor for monitoring load on the CPU, and hence information on load on the system controller 103 is acquired using this tool. More specifically, when a value indicated by this tool is not smaller than a predetermined value, it is determined that the system controller 103 is in a high-load mode, and when the value is smaller than the predetermined value, it is determined that the system controller 103 is in a low-load mode.

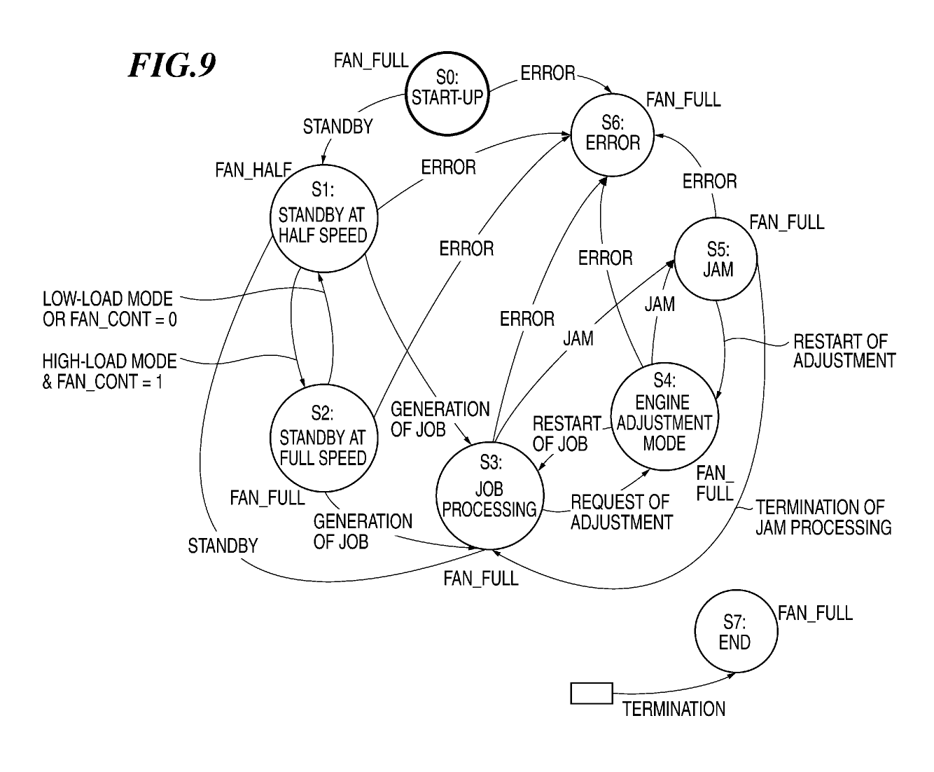

FIG. 9 is a state transition diagram of the image processing apparatus 119 in the case where information on the load state of the system controller 103 is used.

As shown in FIG. 9, in the control of the fan 113 using the information on the load state, the condition A is defined as the flag FAN_CONT=1 and the high-load mode, and the condition B is defined as the flag FAN_CONT=0 or the low-load mode.

Note that in a case where the flag FAN_CONT is determined according to the temperature slope-based temperature characteristic measurement process shown in FIG. 4, execution of this process increases the load on the system controller 103, and hence when during execution of the FIG. 4 process, determination of whether or not to change the state is not executed.

Further, the load on the system controller 103 can be determined not only by the above-mentioned tool, but also by determining the low-load mode or the high-load mode in advance as an attribute of load to each of jobs other than an image processing job to be processed by the image processing apparatus 119.

For example, if the high-load mode is set as an attribute of the web-browsing operation in advance, the system controller 103 is determined to be in the high-load mode during execution of the web-browsing operation.

Further, the load state may be determined based on the number of functions used by the system controller 103 when a job other than the image processing job is processed. As described above, the system controller 103 acquires information on load from the tool for measuring the load, or acquires information on load determined by the processing being executed.

When determining an attribute of load of a job other than the image processing job, or when determining a load state based on the number of functions, a result of actual measurement of an increase in temperature by experiment is used.

As described above, the system controller 103 acquires information on load on the device, and when the load indicated by the acquired information is not lower than the predetermined load, and also a measurement result of temperature characteristics indicates a larger degree of increase in temperature than the predetermined reference value, the system controller 103 controls the fan 113 to operate at a predetermined air flow rate.

Further, the system controller 103 acquires information on load on the device, and when the load indicated by the acquired information is lower than the predetermined load, or a measurement result of temperature characteristics indicates a smaller degree of increase in temperature than the predetermined reference value, the system controller 103 controls the fan 113 to operate at an air flow rate lower than the predetermined air flow rate.

According to the above-described embodiment, it is possible to switch the operation of the fan between a full-speed state and a half-speed state according to the operating condition, the operating environment, and performance of an individual unit of the system controller 103.

That is, it is possible to make most effective use of quietness performance of the apparatus, and provide a comfortable operational environment of the image processing apparatus 119.

Aspects of the present invention can also be realized by a computer of a system or apparatus (or devices such as a CPU or MPU) that reads out and executes a program recorded on a memory device to perform the functions of the above-described embodiment, and by a method, the steps of which are performed by a computer of a system or apparatus by, for example, reading out and executing a program recorded on a memory device to perform the functions of the above-described embodiment. For this purpose, the program is provided to the computer for example via a network or from a recording medium of various types serving as the memory device (e.g., computer-readable medium).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-257437, filed Nov. 26, 2012, which is hereby incorporated by reference herein in its entirety.

What is claimed is:

1. An electronic apparatus that includes a semiconductor device and is capable of controlling a flow rate of air from a fan for cooling the semiconductor device, comprising:
a measurement unit configured to measure temperature characteristics indicative of a degree of increase in temperature of the semiconductor device; and
a control unit configured to control the fan to operate at a predetermined air flow rate in a case where a result of the temperature characteristics measurement by said measurement unit indicates a degree of increase in temperature not smaller than a predetermined reference value, and control the fan to operate at an air flow rate lower than the predetermined air flow rate in a case where the measurement result indicates a degree of increase in temperature smaller than the predetermined reference value.

2. The electronic apparatus according to claim 1, wherein said measurement unit measures the temperature characteristics based on a time period which elapses after a load is applied to the semiconductor device, and temperature of the semiconductor device which increases after the load starts to be applied to the semiconductor device.

3. The electronic apparatus according to claim 2, wherein said measurement unit measures the temperature characteristics, based on temperature of the semiconductor device measured when a predetermined time elapses after a load starts to be applied to the semiconductor device, by determining a rate of increase in the temperature.

4. The electronic apparatus according to claim 2, wherein said measurement unit measures the temperature characteristics by determining whether or not temperature of the semiconductor device increases to a predetermined temperature before a predetermined time elapses after a load starts to be applied to the semiconductor device.

5. The electronic apparatus according to claim 1, wherein said control unit controls the fan to operate at the predetermined air flow rate when temperature of the semiconductor device is not lower than a predetermined temperature, and also a result of the temperature characteristics measurement indicates a degree of increase in temperature not smaller than the predetermined reference value.

6. The electronic apparatus according to claim 1, wherein said control unit controls the fan to operate at the air flow rate lower than the predetermined air flow rate when temperature of the semiconductor device is lower than a predetermined temperature, or the result of the temperature characteristics measurement indicates a degree of increase in temperature smaller than the predetermined reference value.

7. The electronic apparatus according to claim 1, wherein said control unit acquires information on load on the semiconductor device, and controls the fan to operate at the predetermined air flow rate, when the load indicated by the acquired information is not lower than a predetermined load, and also the result of the temperature characteristics measurement indicates a degree of increase in temperature not smaller than the predetermined reference value.

8. The electronic apparatus according to claim 1, wherein said control unit acquires information on load on the semiconductor device, and controls the fan to operate at the air flow rate lower than the predetermined air flow rate, when the load indicated by the acquired information is lower than a predetermined load, or the measurement result indicates a degree of increase in temperature smaller than the predetermined reference value.

9. The electronic apparatus according to claim 7, wherein said control unit acquires the information on load on the semiconductor device from a tool for measuring load or from information concerning processing being executed.

10. The electronic apparatus according to claim 1, wherein said measurement unit measures the temperature characteristics at predetermined time intervals.

11. A method of controlling an electronic apparatus that includes a semiconductor device and is capable of controlling a flow rate of air from a fan for cooling the semiconductor device, comprising:
measuring temperature characteristics indicative of a degree of increase in temperature of the semiconductor device; and
controlling the fan to operate at a predetermined air flow rate in a case where a result of the temperature characteristics measurement by said measuring indicates a degree of increase in temperature not smaller than a predetermined reference value, and controlling the fan to operate at an air flow rate lower than the predetermined air flow rate in a case where the result of the temperature characteristics measurement indicates a degree of increase in temperature smaller than the predetermined reference value.

12. The method according to claim 11, wherein said measuring includes measuring the temperature characteristics based on a time period which elapses after a load is applied to the semiconductor device, and temperature of the semiconductor device which increases after the load starts to be applied to the semiconductor device.

13. The method according to claim 12, wherein said measuring includes measuring the temperature characteristics, based on temperature of the semiconductor device measured when a predetermined time elapses after a load starts to be applied to the semiconductor device, by determining a rate of increase in the temperature.

14. The method according to claim 12, wherein said measuring includes measuring the temperature characteristics by determining whether or not temperature of the semiconductor device increases to a predetermined temperature before a predetermined time elapses after a load starts to be applied to the semiconductor device.

15. The method according to claim 11, wherein said controlling includes controlling the fan to operate at the predetermined air flow rate when temperature of the semiconductor device is not lower than a predetermined temperature, and also a result of the temperature characteristics measurement indicates a degree of increase in temperature not smaller than the predetermined reference value.

16. The method according to claim 11, wherein said controlling includes controlling the fan to operate at the air flow rate lower than the predetermined air flow rate when temperature of the semiconductor device is lower than a predetermined temperature, or the result of the temperature characteristics measurement indicates a degree of increase in temperature smaller than the predetermined reference value.

17. The method according to claim 11, wherein said controlling includes acquiring information on load on the semiconductor device, and controlling the fan to operate at the predetermined air flow rate, when the load indicated by the acquired information is not lower than a predetermined load, and also the result of the temperature characteristics measurement indicates a degree of increase in temperature not smaller than the predetermined reference value.

18. The method according to claim 11, wherein said controlling includes acquiring information on load on the semiconductor device, and controlling the fan to operate at the air flow rate lower than the predetermined air flow rate, when the load indicated by the acquired information is lower than a predetermined load, or the result of the temperature characteristics measurement indicates a degree of increase in temperature smaller than the predetermined reference value.

19. The method according to claim 17, wherein said controlling includes acquiring the information on load on the semiconductor device from a tool for measuring load or from information concerning processing being executed.

20. The method according to claim 11, wherein said measuring includes measuring the temperature characteristics at predetermined time intervals.

21. A non-transitory computer-readable storage medium storing a computer-executable program for executing a method of controlling an electronic apparatus that includes a semiconductor device and is capable of controlling a flow rate of air from a fan for cooling the semiconductor device,
wherein the method comprises:
measuring temperature characteristics indicative of a degree of increase in temperature of the semiconductor device; and
controlling the fan to operate at a predetermined air flow rate in a case where a result of the temperature characteristics measurement by said measuring indicates a degree of increase in temperature not smaller than a predetermined reference value, and controlling the fan to operate at an air flow rate lower than the predetermined air flow rate in a case where the result of the temperature characteristics measurement indicates a degree of increase in temperature smaller than the predetermined reference value.
